(19) United States
(12) Patent Application Publication
(10) Pub. No.: US 2025/0386470 A1
(43) Pub. Date: Dec. 18, 2025

(54) HEAT DISSIPATION DEVICE FOR AN ELECTRONIC COMPUTER

(71) Applicant: CONTINENTAL AUTOMOTIVE TECHNOLOGIES GMBH, Hannover (DE)

(72) Inventor: Jean-Philippe BEKAERT, Montigny le Bretonneux (FR)

(73) Assignee: CONTINENTAL AUTOMOTIVE TECHNOLOGIES GMBH, Hannover (DE)

(21) Appl. No.: 18/877,460

(22) PCT Filed: Jun. 20, 2023
(86) PCT No.: PCT/EP2023/066687

§ 371 Date: Dec. 20, 2024

(30) Foreign Application Priority Data
Jul. 5, 2022 (FR) 2206810

(51) Int. Cl. H05K 7/20; H01Q 1/02; H01Q 1/32

(52) U.S. Cl. CPC H05K 7/20863; H01Q 1/02; H01Q 1/3275

(57) ABSTRACT

A heat sink device for an electronic computer housed in the roof of a vehicle, including a radial fan housed in the thickness of a casing of said computer and configured to circulate an air flow from a lower face of the casing toward the top of the casing via a ramp positioned facing the outlet of the fan. The bottom portion of the ramp is truncated in order to form a spacing between the ramp and the fan and to enable a liquid to flow from an upper portion toward the bottom of the casing, and a deflector is positioned at the outlet of the fan in order to direct the air flow toward the ramp.

### CROSS REFERENCE TO RELATED APPLICATIONS

This application is the U.S. National Phase Application of PCT International Application No. PCT/EP2023/066687, filed Jun. 20, 2023, which claims priority to French Application No. 2206810, filed Jul. 5, 2022, the contents of such applications being incorporated by reference herein.

### DESCRIPTION

### Field of the Invention

The invention belongs to the field of thermal control of electronic devices and relates in particular to a device for cooling an electronic device intended to be incorporated into the roof of a vehicle.

### Background of the Invention

Nowadays, the majority of modern vehicles are configured to receive different types of radiofrequency signals. They are, for example, configured to receive FM or digital radio signals, signals transmitted by geolocation satellites, to establish Wi-Fi connections, Bluetooth connections, or to establish communications through a cellular access network. These communication technologies do not operate in the same frequency bands and require specific configurations for antennas and for the demodulators.

In order to make it easier for them to be incorporated into a vehicle, these communication technologies are most often incorporated into the same device, for example a TCU (telecom control unit). The TCU may also incorporate the antennas required for receiving and emitting radiofrequency signals. This is then referred to as an intelligent antenna or intelligent antenna module (IAM). This type of antenna is generally intended to be incorporated between the headliner and the roof of the vehicle, the antennas protruding above the roof through an orifice provided for this purpose. The antennas may be covered by a cover, which is for example in the form of a shark fin.

Such an antenna module incorporated into the roof is thus exposed to high temperatures and to a risk of water infiltrating via the orifice formed in the roof through which the antennas protrude. The module must also be compact in order to be incorporated between the headliner and the roof.

In order to meet these various requirements, a roof antenna module for a vehicle as depicted in FIG. 1 has been proposed. The antenna module comprises a frame 101 and a cover 102 forming a casing in which a circuit board 103 and a radial fan 105 are housed. The frame 101 is configured to form a ramp 108 arranged opposite a lateral outlet 110 of the fan 105 and configured to force an air flow 109 along the upper portion of the frame 101.

The antenna module in FIG. 1 is incorporated between a headliner 107 and the roof 100 of the vehicle. An air guide 106 is interposed between the headliner 107 and the lower cover 102 of the antenna module, so that the air penetrates through a grille 108 before being guided by the guide 106 toward the inlet 111 of the fan 105, so as to create an air flow passing through the lower face and the upper face of the antenna module in order to cool components 104 of the circuit board 103.

In order to protect the circuit board 103 in the event of infiltration of water, a seal 112 is provided. The seal 112 makes it possible to prevent a liquid flowing down the ramp 108 from being able to reach the circuit board 103.

Such a configuration is not entirely satisfactory.

Specifically, introducing the seal 112 and compressing it results in a loss of nearly 25% of the available thickness. This accordingly decreases the rotor height of the fan. The volume of air circulated by the latter is therefore reduced and limits the flowrate-to-noise ratio (a small fan has to rotate faster to provide the same flowrate).

The installation of the seal 112 requires the size of the cover to be increased and screws to be introduced in order to ensure it is compressed and sealed. The mass of the computer, its assembly time, its cost and its mass are high.

There is thus a need for a heat sink device that does not have the abovementioned disadvantages.

### SUMMARY OF THE INVENTION

To this end, a heat sink device for an electronic computer is proposed, comprising a radial fan housed in the thickness of a casing of said computer and configured to circulate an air flow from a lower face of the casing toward the top of the casing via a ramp positioned facing the outlet of the fan.

The device is distinguished in that:
the bottom portion of the ramp is truncated in order to form a spacing between said ramp and the fan and to enable a liquid to flow from an upper portion toward the bottom of the casing, and
a deflector is positioned at the outlet of the fan in order to direct the air flow toward said ramp.

The deflector makes it possible to introduce a clearance in order to prevent water from penetrating into the compartment of the circuit while at the same time limiting the recirculation of the air between the outlet and the inlet by way of the spacing formed between the ramp and the fan.

This enables a liquid such as rainwater to freely flow from the upper face of the casing toward the bottom of the casing without requiring the use of a seal. The absence of a seal makes it possible to use a thicker fan that may rotate more slowly for an equivalent flowrate. This decreases the noise. The size of the cover may also be reduced, thus limiting the mass of the computer. Finally, the assembly of the product is easier and less expensive.

According to one particular embodiment, the deflector is formed by a portion of the stator of the fan.

The deflector is thus formed in the material of the fan. This limits its weight and makes it easier to install.

According to one particular embodiment, the deflector is oriented so as to direct the air flow in a direction substantially parallel to the ramp.

Aligning the deflector with the gradient of the ramp further limits the recirculation of air and improves the cooling performance.

### BRIEF DESCRIPTION OF THE DRAWINGS

Other aspects, aims and advantages of aspects of the invention will become apparent upon reading the following description of one of its embodiments, which is given by way of nonlimiting example. Aspects of the invention will also be better understood in light of the appended drawings, in which:

FIG. 1 is a sectional view of an antenna module from the prior art,

FIG. 2 is an exploded view of an antenna module according to one particular embodiment of the invention,

FIG. 3 is a sectional view of an antenna module according to one particular embodiment,

FIG. 4 is a sectional view of an antenna module according to one particular embodiment in which air flows are depicted.

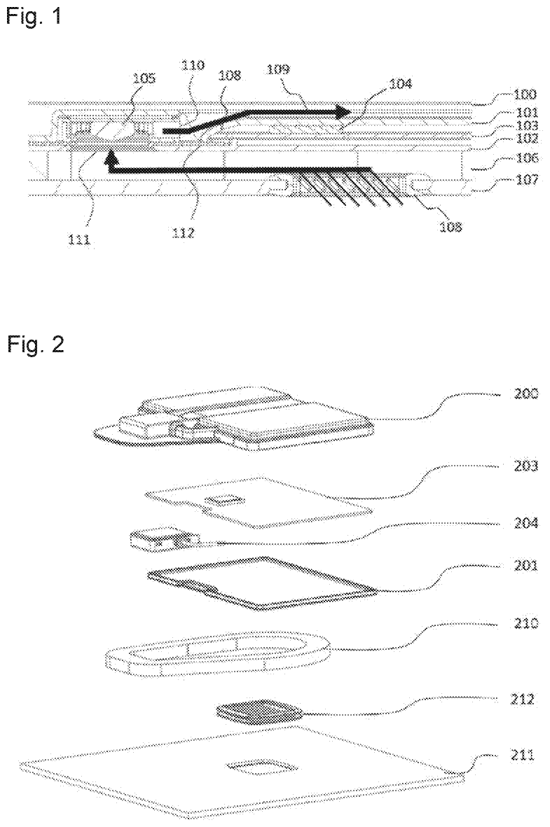

### DETAILED DESCRIPTION OF EXEMPLARY EMBODIMENTS

FIG. 2 is an exploded view of an antenna module comprising a cooling device according to one particular embodiment of the invention. The antenna module is, for example, installed in the roof of a vehicle, between the headliner and the roof.

The antenna module comprises a casing composed of a frame 200 and of a lower cover 201 accommodating a circuit board 203 of a computer. The frame is, for example, made from a metal such as aluminum or magnesium.

For the purpose of cooling the circuit board 203, a radial fan 204 is housed in the thickness of the antenna module. More precisely, the fan is placed in a housing provided for this purpose in the frame 200. The fan 204 and the housing in which it is placed are configured to draw in the air from below the antenna module and to blow it via a lateral outlet onto the upper portion of the frame.

FIG. 2 likewise shows a headliner 211 equipped with a grille 212 intended to enable the air drawn in by the fan to pass through the headliner and to circulate from the cabin of the vehicle toward the top of the frame 200. Finally, FIG. 2 shows an air guide 210, which is arranged between the bottom of the antenna module and the headliner 211 and has the purpose, on the one hand, of preventing the headliner from being pressed against the fan by the drawing-in, and, on the other hand, of forcing a circulation of air onto the bottom of the casing. For this purpose, the ventilation grille 212 is not placed vertically in alignment with the fan 204, but beneath the cover 201 so that the drawn-in air is forced to circulate along the cover 201 before penetrating into the fan 204.

Thus, the air guide 210 interposed between the headliner 211 and the bottom of the antenna module makes it possible to guide the air that penetrates through the grille 212 toward the inlet of the fan 204, so as to create an air flow passing through the lower face of the antenna module in order to cool the circuit board 203.

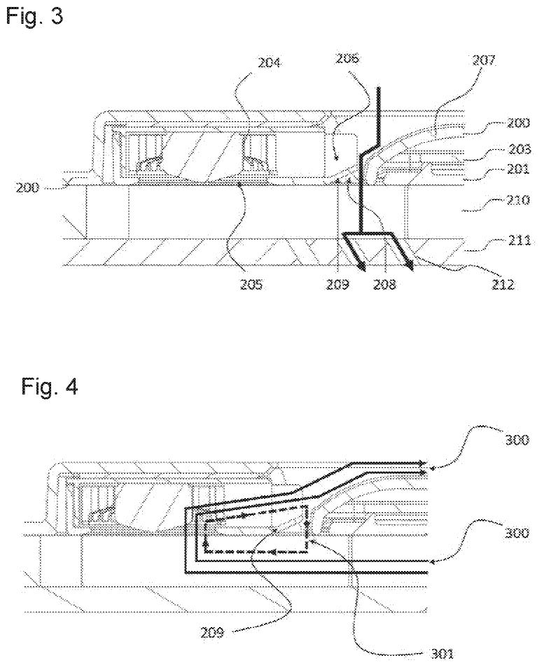

FIG. 3 is a sectional view of an antenna module according to one particular embodiment. FIG. 3 more precisely shows the portion of the antenna module into which the fan 204 is incorporated. For the sake of clarity, it should be noted that the same references in the figures are used to designate identical elements.

FIG. 3 shows the inlet 205 of the fan 204 on the lower face of the antenna module and the lateral outlet 206 toward a ramp 207 formed by a portion of the frame 200 in order to guide the air flow along the upper face of the frame.

In one particular embodiment, the lower portion of the ramp 207 is truncated so as to form a space 208 between the outlet 206 of the fan 204 and the ramp 207. This space advantageously enables a liquid flowing down the ramp 207 to flow toward the bottom of the antenna module and the cabin via the grille 212.

In one particular embodiment, the lower end of the ramp 207 forms a lip that covers the edge face of the cover 201 in order to prevent a liquid from being able to infiltrate between the frame and the cover.

In order to prevent the air expelled by the fan from being diverted and drawn in through the spacing 208, the device comprises a deflector 209. The deflector 209 is configured to direct the air flow leaving the fan along the axis of the ramp 207 and thus to limit the recirculation of a portion of the air flow through the space 208 formed for the flow of water. For example, the gradient of the deflector may be substantially equivalent to the gradient of the ramp in order to minimize the angle of incidence of the air flow on the ramp. This improves the efficiency of the fan and enables its rotational speed and/or its size to be reduced compared to a configuration in which the deflector is absent.

In one particular embodiment, the deflector is incorporated onto the stator of the fan and formed in the material of the fan, for example from a thermoplastic material that is lighter than the metal from which the frame is made. However, according to other embodiments, the deflector is incorporated onto the frame and formed in the material of the frame.

FIG. 4 is a sectional view of an antenna module according to one particular embodiment in which air flows are depicted. A first main air flow 300 circulated by the fan may be seen. The air flow 300 penetrates into the fan via the lower face of the antenna module before being directed by the deflector toward the ramp and the upper portion of the casing. A recirculation loop 301, which is limited to a very large extent by the presence of the deflector 209, may also be seen.

The proposed cooling device thus enables a liquid to flow, for example for infiltrated rainwater to flow, from the top of the antenna module to the cabin without requiring a seal to be provided between the cover and the frame. The space freed up by the absence of a seal makes it possible to use a fan with a larger volume, thus making it possible for the rotational speed thereof to be reduced, thereby advantageously limiting the noise and the energy consumed.

1. A heat sink device for an electronic computer comprising a casing composed of a frame and of a lower cover, a radial fan housed in the thickness of the casing, and a ramp formed by a portion of the frame positioned facing the outlet of the fan, the fan being configured to circulate an air flow from a lower face of the casing toward the top of the casing via said ramp, the device comprising:
the bottom portion of the ramp is truncated in order to form a spacing between said ramp and the fan and to enable a liquid to flow from an upper portion toward the bottom of the casing, and
a deflector is positioned at the outlet of the fan in order to direct the air flow toward said ramp.

2. The device as claimed in claim 1, such that the deflector is formed by a portion of the stator of the fan.

3. The device as claimed in claim 1, wherein the deflector is oriented so as to direct the air flow in a direction substantially parallel to the ramp.

4. A roof antenna module for a vehicle comprising a cooling device as claimed in claim 1.

5. A vehicle comprising an antenna module as claimed in claim 4.

6. The device as claimed in claim 2, wherein the deflector is oriented so as to direct the air flow in a direction substantially parallel to the ramp.
